(19) United States
(12) Patent Application Publication
(10) Pub. No.: US 2014/0008104 A1
(43) Pub. Date: Jan. 9, 2014

(54) RESISTANCE-FORMED SUBSTRATE AND METHOD FOR MANUFACTURING SAME

(71) Applicants: Yasuhiro Sugaya, Osaka (JP); Hiroyuki Ishitomi, Osaka (JP); Tadashi Nakamura, Mie (JP)

(72) Inventors: Yasuhiro Sugaya, Osaka (JP); Hiroyuki Ishitomi, Osaka (JP); Tadashi Nakamura, Mie (JP)

(73) Assignee: Panasonic Corporation, Osaka (JP)

(21) Appl. No.: 14/001,517

(22) PCT Filed: Jan. 29, 2013
(86) PCT No.: PCT/JP2013/000454

§ 371 Date: Aug. 26, 2013

(30) Foreign Application Priority Data
Feb. 8, 2012 (JP) 2012-024701
Nov. 2, 2012 (JP) 2012-242429
Nov. 2, 2012 (JP) 2012-242430

(51) Int. Cl. H05K 3/30; H05K 1/16

(52) U.S. Cl. CPC H05K 3/303; H05K 1/167
USPC 174/251; 29/846

(57) ABSTRACT

A resistance-formed substrate includes a first insulating layer, a first wiring formed on a first surface of the first insulating layer, a thin-film resistance layer formed on a second surface of the first insulating layer, and a first via-hole conductor. The first via-hole conductor penetrates through the first insulating layer, and is electrically connected to the first wiring and the thin-film resistance layer. The first via-hole conductor includes a metal part including a low-melting point metal and a high-melting point metal, and a paste resin part. The low-melting point metal includes tin and bismuth, and has a melting point of 300° C. or lower. The high-melting point metal includes at least one of copper and silver, and has a melting point of 900° C. or higher. The first via-hole conductor is in contact with the thin-film resistance layer at both the paste resin part and the metal part.

### TECHNICAL FIELD

The present invention relates to a resistance-formed substrate that is one type of wiring boards used in various electronic apparatuses and a method for manufacturing the same.

### BACKGROUND ART

A printed wiring board including a thin-film resistor body disposed between insulating layers is known. FIG. 18 is a sectional schematic view of a conventional resistance-formed substrate. Resistor body 910 is formed on insulating part 900. Insulating part 920 is formed on resistor body 910. Insulating part 930 is formed on insulating part 920. Wiring 940 is formed on insulating part 930. Wiring 940 and resistor body 910 are coupled to each other by conductive part 950. As mentioned above, a resistance-formed substrate is configured. Note here that prior art literatures related to the present invention include Patent Literature 1.

### CITATION LIST

### Patent Literature

Patent Literature 1: Japanese Patent Application Unexamined Publication No. 2009-135196

### SUMMARY OF THE INVENTION

A resistance-formed substrate includes a first insulating layer, a first wiring formed on a first surface of the first insulating layer, a thin-film resistance layer formed on a second surface of the first insulating layer, and a first via-hole conductor. The first via-hole conductor penetrates through the first insulating layer, and is electrically connected to the first wiring and the thin-film resistance layer. A main component of the thin-film resistance layer is nickel. The first via-hole conductor includes a metal part including a low-melting point metal and a high-melting point metal, and a paste resin part. The low-melting point metal includes tin and bismuth, and has a melting point of 300° C. or lower. The high-melting point metal includes at least one of copper and silver, and has a melting point of 900° C. or higher. The first via-hole conductor is brought into contact with the thin-film resistance layer at both the paste resin part and the metal part.

### BRIEF DESCRIPTION OF THE DRAWINGS

FIG. 1 is a sectional schematic view of a resistance-formed substrate in accordance with an exemplary embodiment of the present invention.

FIG. 2 is a sectional schematic view for illustrating a connection portion between a thin-film resistance layer and a via-hole conductor of the resistance-formed substrate in accordance with the exemplary embodiment of the present invention.

FIG. 3 is a sectional schematic view for illustrating the connection portion between the via-hole conductor and the thin-film resistance layer of the resistance-formed substrate in accordance with the exemplary embodiment of the present invention.

FIG. 4 is another sectional schematic view for illustrating a connection portion between a thin-film resistance layer and a via-hole conductor of a resistance-formed substrate in accordance with the exemplary embodiment of the present invention.

FIG. 5 is another sectional schematic view for illustrating the connection portion between the via-hole conductor and the thin-film resistance layer of the resistance-formed substrate in accordance with the exemplary embodiment of the present invention.

FIG. 6A is a sectional view showing a method for manufacturing a resistance-formed substrate in accordance with the exemplary embodiment of the present invention.

FIG. 6B is a sectional view showing the method for manufacturing the resistance-formed substrate in accordance with the exemplary embodiment of the present invention.

FIG. 6C is a sectional view showing the method for manufacturing the resistance-formed substrate in accordance with the exemplary embodiment of the present invention.

FIG. 6D is a sectional view showing the method for manufacturing the resistance-formed substrate in accordance with the exemplary embodiment of the present invention.

FIG. 7A is a sectional view showing the method for manufacturing the resistance-formed substrate in accordance with the exemplary embodiment of the present invention.

FIG. 7B is a sectional view showing the method for manufacturing the resistance-formed substrate in accordance with the exemplary embodiment of the present invention.

FIG. 7C is a sectional view showing the method for manufacturing the resistance-formed substrate in accordance with the exemplary embodiment of the present invention.

FIG. 8A is a sectional view showing the method for manufacturing the resistance-formed substrate in accordance with the exemplary embodiment of the present invention.

FIG. 8B is a sectional view showing the method for manufacturing the resistance-formed substrate in accordance with the exemplary embodiment of the present invention.

FIG. 8C is a sectional view showing the method for manufacturing the resistance-formed substrate in accordance with the exemplary embodiment of the present invention.

FIG. 9A is a sectional view showing a method for manufacturing a resistance-formed substrate including a buildup portion in accordance with the exemplary embodiment of the present invention.

FIG. 9B is a sectional view showing the method for manufacturing the resistance-formed substrate including the buildup portion in accordance with the exemplary embodiment of the present invention.

FIG. 9C is a sectional view showing the method for manufacturing the resistance-formed substrate including the buildup portion in accordance with the exemplary embodiment of the present invention.

FIG. 10A is a sectional view showing the method for manufacturing the resistance-formed substrate including the buildup portion in accordance with the exemplary embodiment of the present invention.

FIG. 10B is a sectional view showing the method for manufacturing the resistance-formed substrate including the buildup portion in accordance with the exemplary embodiment of the present invention.

FIG. 11A is a sectional view showing the method for manufacturing the resistance-formed substrate including the buildup portion in accordance with the exemplary embodiment of the present invention.

FIG. 11B is a sectional view showing the method for manufacturing the resistance-formed substrate including the buildup portion in accordance with the exemplary embodiment of the present invention.

FIG. 12A is a sectional schematic view for illustrating an effect of a protruding portion in accordance with the exemplary embodiment of the present invention.

FIG. 12B is a sectional schematic view for illustrating the effect of the protruding portion in accordance with the exemplary embodiment of the present invention.

FIG. 13A is an electron micrograph of a contact portion between a high-melting point metal in the via-hole conductor and the thin-film resistance layer in accordance with the exemplary embodiment of the present invention.

FIG. 13B is a mapping view of FIG. 13A.

FIG. 13C is a schematic view of FIG. 13A.

FIG. 14A is an electron micrograph of a contact portion between a low-melting point metal in the via-hole conductor and the thin-film resistance layer in accordance with the exemplary embodiment of the present invention.

FIG. 14B is a mapping view of FIG. 14A.

FIG. 14C is a schematic view of FIG. 14A.

FIG. 14D is a schematic view of the contact portion between the low-melting point metal in the via-hole conductor and the thin-film resistance layer in accordance with the exemplary embodiment of the present invention.

FIG. 15A is an electron micrograph of the contact portion between the low-melting point metal in the via-hole conductor and the thin-film resistance layer in accordance with the exemplary embodiment of the present invention.

FIG. 15B is a schematic view of FIG. 15A.

FIG. 15C is an electron micrograph of the contact portion between the low-melting point metal in the via-hole conductor and the thin-film resistance layer in accordance with the exemplary embodiment of the present invention.

FIG. 15D is a schematic view of FIG. 15C.

FIG. 16 is a sectional schematic view showing a via-hole conductor in accordance with the exemplary embodiment of the present invention.

FIG. 17 is a sectional schematic view showing a via-hole conductor in a case where a copper pad is formed in accordance with the exemplary embodiment of the present invention.

FIG. 18 is a sectional schematic view of a conventional resistance-formed substrate.

### DETAILED DESCRIPTION OF THE PREFERRED EMBODIMENT

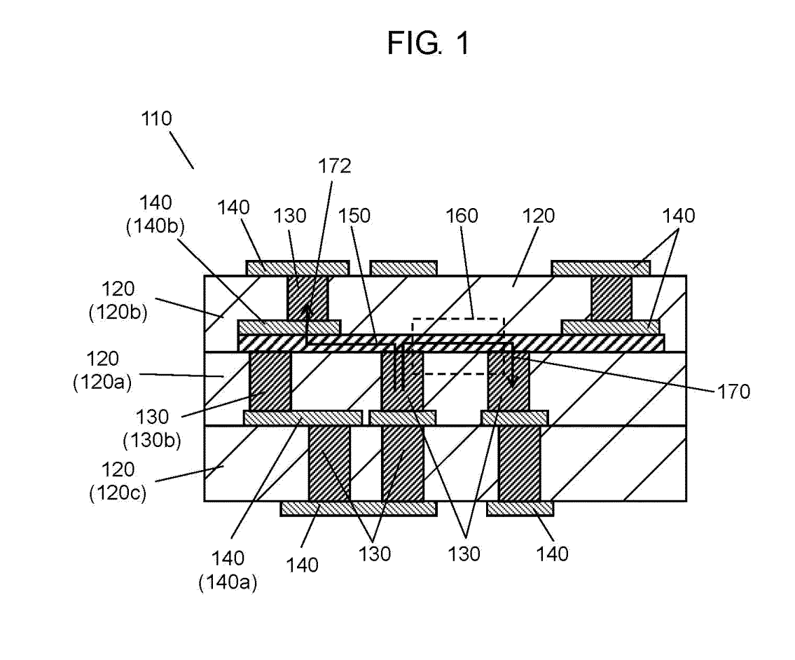

FIG. 1 is a sectional schematic view of a resistance-formed substrate in accordance with an exemplary embodiment of the present invention. Resistance-formed substrate 110 includes first insulating layer 120a (insulating layer 120), first wiring 140a (wiring 140) formed on a first surface of first insulating layer 120a, thin-film resistance layer 150 formed on a second surface of first insulating layer 120a, and first via-hole conductor 130b (via-hole conductor 130). First via-hole conductor 130b penetrates through first insulating layer 120a and is electrically connected to first wiring 140a and thin-film resistance layer 150. First via-hole conductor 130b is brought into direct contact with wiring 140 and thin-film resistance layer 150. A main component of thin-film resistance layer 150 is nickel. Second wiring 140b (wiring 140) is formed on the upper part of thin-film resistance layer 150. Wiring 140 is made of cupper. Note here that “formed on a first surface or a second surface” include “formed on a surface” and “formed at the inner side of a surface.”

Furthermore, second insulating layer 120b (120) may be formed on first insulating layer 120a. Third insulating layer 120c (120) may be formed below first insulating layer 120a. Furthermore, second insulating layer 120b and/or third insulating layer 120c may be provided with wiring 140 and/or thin-film resistance layer 150. Then, wiring 140 and thin-film resistance layer 150 may be coupled to each other by via-hole conductor 130.

As insulating layer 120, a cured product of prepreg is used. For example, the prepreg is formed by impregnating glass fiber with epoxy resin. A thickness of insulating layer 120 is desirably 5 μm or more, more desirably 10 μm or more, and further desirably 15 μm or more. Prepreg having a thickness of less than 5 μm may have an insufficient electric insulation property. Furthermore, prepreg using a heat-resistant resin film (for example, a polyimide film) having a solder heat resistance property instead of core material such as glass fiber and including a resin layer as an adhesion layer on at least one surface of the heat-resistant resin film may be used.

When an insulating layer including a polyimide film as core material is used as insulating layer 120, the resistance-formed substrate can be made to be thinner.

Furthermore, a thickness of wiring 140 is desirably 5 μm or more, and further desirably 10 μm or more. A thickness of wiring 140 of less than 5 μm may increase a resistance value. Furthermore, a thickness of wiring 140 is desirably 200 μm or less, and further desirably 100 μm or less. A thickness of wiring 140 of more than 200 μm may affect size reduction and increase of density of the resistance-formed substrate.

A diameter of via-hole conductor 130 is desirably 30 μm or more and 300 μm or less. In via-hole conductor 130 having a diameter of less than 30 μm, via resistance may be increased and reliability of via connection may become insufficient. Furthermore, the diameter of via-hole conductor 130 of more than 300 μm makes it difficult to reduce the size and to increase the density in the resistance-formed substrate.

A thickness of thin-film resistance layer 150 is desirably 10 μm or less, and further desirably 5 μm or less. When the thickness of thin-film resistance layer 150 is more than 5 μm, thin-film resistance layer 150 becomes expensive, and a level difference between thin-film resistance layer 150 and a peripheral portion is increased.

Arrow 170 indicates an electric current. As shown by arrow 170, the electric current flows from one via-hole conductor 130 to the other via-hole conductor 130 through thin-film resistance layer 150. The electric current may flow as shown by arrow 172. Furthermore, it is desirable that thin-film resistance layer 150 is brought into surface contact with a surface of copper foil that forms wiring 140b. When thin-film resistance layer 150 is brought into surface contact with a surface of wiring 140b, connection between thin-film resistance layer 150 and wiring 140b becomes stable. Furthermore, it is preferable that thin-film resistance layer 150 is previously formed on a surface of copper foil that forms wiring 140b. By using the copper foil which has been previously formed on the surface of thin-film resistance layer 150, it is possible to remove thin-film resistance layer 150 as an unnecessary part together with copper foil, or to remove a part of thin-film resistance layer 150 with the copper foil left, or to remove a part of the copper foil with thin-film resistance layer 150 left.

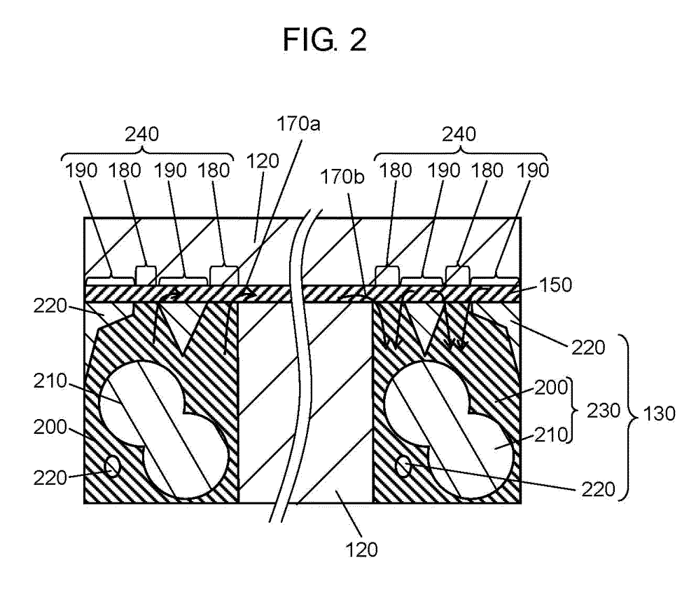

FIG. 2 is a sectional schematic view for illustrating a connection portion between thin-film resistance layer 150 and via-hole conductor 130 in resistance-formed substrate 110. FIG. 2 corresponds to, for example, a part surrounded by dotted line 160 in FIG. 1.

Via-hole conductor 130 includes paste resin part 220 and metal part 230. Metal part 230 includes low-melting point metal 200 and high-melting point metal 210. First via-hole conductor 130 is brought into contact with thin-film resistance layer 150 at both paste resin part 220 and metal part 230 thereof.

Examples of low-melting point metal 200 include a molten product of low-melting point metal powder of solder or the like having a melting point of 300° C. or lower and including tin and bismuth, or a tin-copper based alloy obtained by alloying solder with copper powder, or a tin-based alloy obtained by alloying solder with silver powder, or alloys or intermetallic compounds thereof. Examples of high-melting point metal 210 include high-melting point metal powders having a melting point of 900° C. or higher and consisting of at least one of copper and silver, or an aggregated product thereof, or a lump obtained by integrating thereof via surface contact portions thereof.

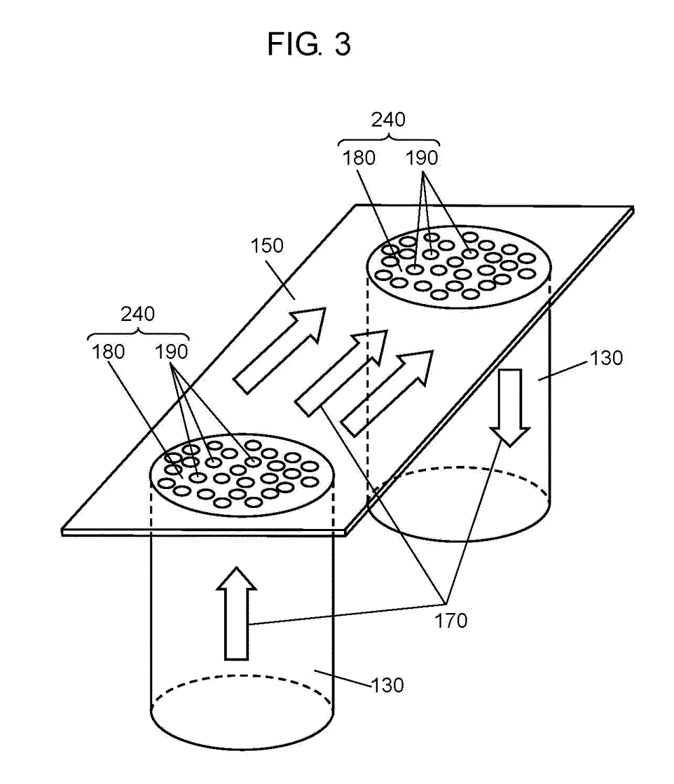

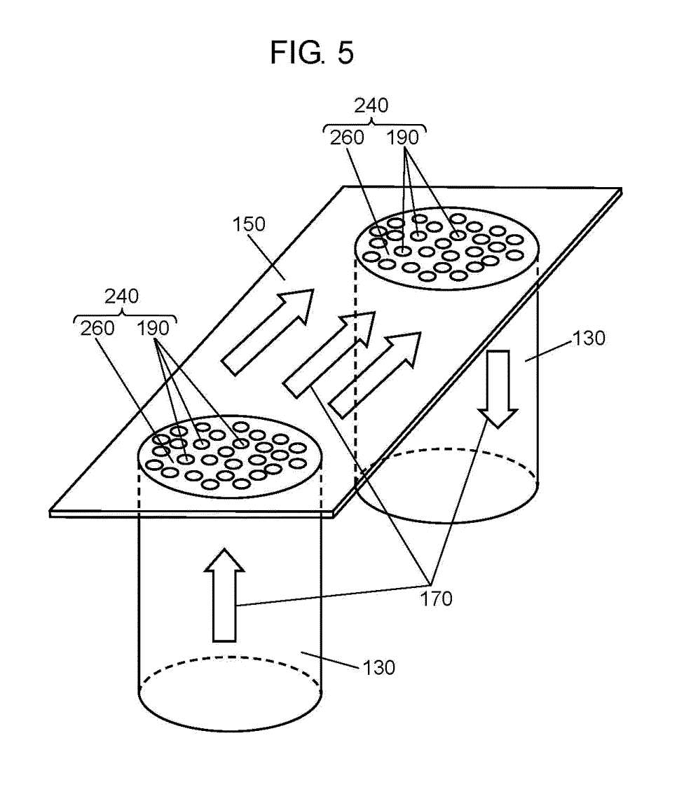

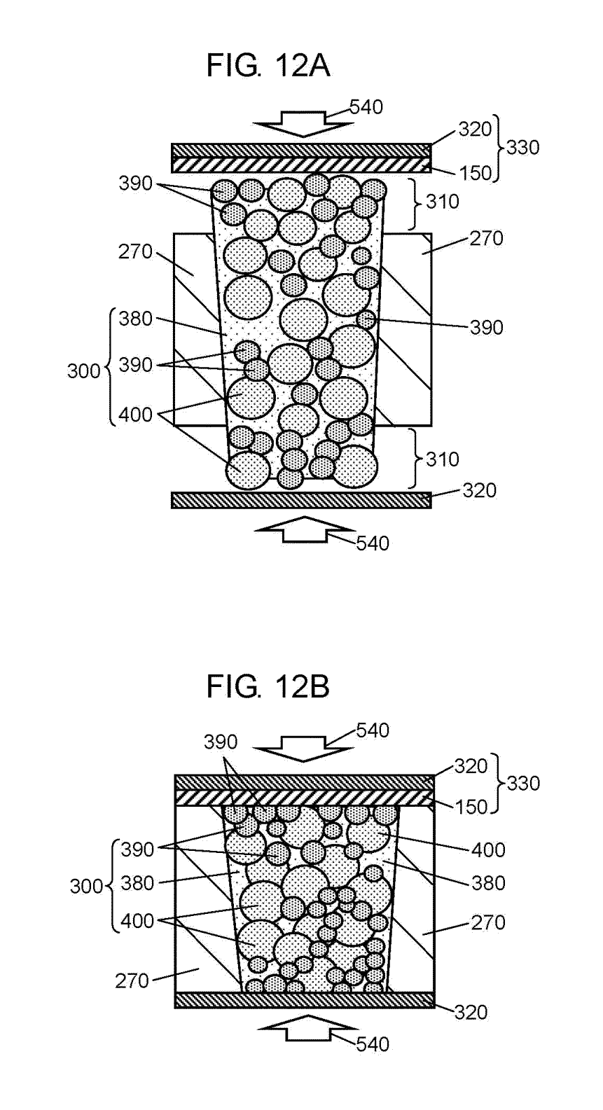

Furthermore, paste resin part 220 is a cured product of a resin component or the like included in conductive paste 300 (see FIG. 12A). Paste resin part 220 is a portion of resin component of conductive paste 300 remaining as one type of resist inside via-hole conductor 130. A part of paste resin part 220 remains inside via-hole conductor 130 in a dotted state (or in a network state, or a mesh state, or at random) in a state in which paste resin part 220 is brought into contact with the surface of thin-film resistance layer 150. The remaining paste resin part 220 relieves stress concentration in an interface region as shown in, for example, FIG. 3 and FIG. 5 mentioned below.

Via-hole conductor 130 includes paste resin part 220, low-melting point metal 200, and high-melting point metal 210. Low-melting point metal 200 and high-melting point metal 210 form metal part 230.

A contact portion between thin-film resistance layer 150 and via-hole conductor 130 includes resistance-metal contact portion 180 and resistance-resin contact portion 190.

Resistance-metal contact portion 180 is a contact portion between thin-film resistance layer 150 and metal part 230 composed of low-melting point metal 200 and high-melting point metal 210 (that is, a contact portion between resistor and metal).

Resistance-resin contact portion 190 is a contact portion between thin-film resistance layer 150 and paste resin part 220 (that is, a contact portion between resistor and resin).

Resistance-formed substrate 110 includes resistance-metal contact portion 180 and resistance-resin contact portion 190, and thereby excellent reliability is obtained.

As shown by arrow 170a in FIG. 2, an electric current flows from via-hole conductor 130 to thin-film resistance layer 150 through a plurality of resistance-metal contact portions 180. Furthermore, as shown by arrow 170b, an electric current flows from thin-film resistance layer 150 to via-hole conductor 130 through a plurality of resistance-resin contact portions 190. Even when one via-hole conductor 130 and one thin-film resistance layer 150 are coupled to each other in only one connection portion, they are electrically conducted to each other through a plurality of small and thin resistance-metal contact portions 180 as shown in FIG. 2. Thus, the reliability of the connection portion is enhanced.

When low-resistance high-melting point metal 210 is provided to low-melting point metal 200 of via-hole conductor 130, via resistance of via-hole conductor 130 can be reduced. For example, low-melting point metal 200 having a melting point of 300° C. or less, which is made of, for example, a tin (Sn)-bismuth (Bi) alloy, or a tin (Sn)-copper (Cu) alloy obtained by alloying tin-bismuth solder and a part of copper powder with each other, or a tin (Sn)-silver (Ag) alloy obtained by alloying tin-bismuth solder and a part of silver powder with each other, or alloys or intermetallic compounds thereof, or the like, has a relatively high resistance value. Therefore, when low-melting point metal 200 is provided with high-melting point metal 210 (for example, silver powder or copper powder, or a part of silver powder and copper powder which remain without being alloyed with tin-bismuth solder) having an extremely low resistance value, the via resistance is reduced.

FIG. 2 does not show that high-melting point metal 210 and thin-film resistance layer 150 are in contact with each other. However, high-melting point metal 210 and thin-film resistance layer 150 may be brought into contact with each other.

Furthermore, in FIG. 2, it is preferable that paste resin part 220 is scattered in via-hole conductor 130. When paste resin part 220 is scattered in via-hole conductor 130, stress generated by a difference in thermal expansion coefficient from those of low-melting point metal 200 and high-melting point metal 210 can be relieved. This is because elastic modulus and physical strength of paste resin part 220 are smaller as compared with those of low-melting point metal 200 and high-melting point metal 210.

Furthermore, in FIG. 2, paste resin part 220 may be scattered in an outer periphery of via-hole conductor 130. When paste resin part 220 is scattered in the outer periphery of via-hole conductor 130, adhesion strength between via-hole conductor 130 and insulating layer 120 surrounding via-hole conductor 130 can be enhanced (or an anchoring effect can be expressed).

Furthermore, it is preferable that paste resin part 220 is scattered in the connection portion (or an interface portion) between via-hole conductor 130 and thin-film resistance layer 150. When paste resin part 220 is scattered in a connection portion or an interface portion between via-hole conductor 130 and thin-film resistance layer 150, it is possible to relieve stress generated by a thermal expansion coefficient in metal part 230 made of low-melting point metal 200 and high-melting point metal 210 constituting via-hole conductor 130, a thermal expansion coefficient of thin-film resistance layer 150, or a thermal expansion coefficient of insulating layer 120 that is in close contact with thin-film resistance layer 150.

In FIG. 2, two via-hole conductors 130 are divided by a wavy line. This means that other via holes (not shown) or the like may be provided between two via-hole conductors 130. In this way, a plurality of via-hole conductors 130 are not necessarily adjacent to each other. Not adjacent via-hole conductors 130 and thin-film resistance layer 150 may be electrically coupled to each other. When not-adjacent via-hole conductor 130 and thin-film resistance layer 150 are coupled to each other, thin-film resistance layer 150, which faces via-hole conductor 130 that is not intended to be coupled, may be removed by, for example, etching.

As mentioned above, via-hole conductor 130 in this exemplary embodiment has an excellent connection property with respect to thin-film resistance layer 150. Then, due to this excellent connection stability, the reliability of the connection portion between a thin-film resistance layer incorporated in resistance-formed substrate 110 and via-hole conductor 130 can be enhanced.

Note here that via-hole conductor 130 coupled to thin-film resistance layer 150 includes paste resin part 220, low-melting point metal 200, and high-melting point metal 210 as shown in FIG. 2. However, a via-hole conductor that is not coupled to thin-film resistance layer 150 may not necessarily include paste resin part 220, low-melting point metal 200, and high-melting point metal 210. The via-hole conductor that is not coupled to thin-film resistance layer 150 may be conductive via paste or through-hole plating, which is made of only high-melting point metal 210 (copper powder) and paste resin part 220.

Furthermore, it is desirable that thin-film resistance layer 150 and paste resin part 220 included contained in via-hole conductor 130 are brought into contact with each other directly. Furthermore, it is desirable that thin-film resistance layer 150 and metal part 230 included in via-hole conductor 130 are brought into surface contact with each other directly. Furthermore, it is desirable that thin-film resistance layer 150 and low-melting point metal 200 included in via-hole conductor 130 are brought into surface contact with each other. Furthermore, thin-film resistance layer 150 and paste resin part 220 included in via-hole conductor 130 may be brought into contact with each other via a surface contact portion.

Next, with reference to FIG. 3, a structure of the connection portion between via-hole conductor 130 and thin-film resistance layer 150 in resistance-formed substrate 110 is described.

FIG. 3 is a sectional schematic view for illustrating the connection portion between the via-hole conductor and the thin-film resistance layer in accordance with the exemplary embodiment of the present invention. FIG. 3 schematically shows, for example, a part shown by dotted line 160 in FIG. 1 mentioned above.

Resistance-via hole conductor contact portion 240 that is a connection portion between via-hole conductor 130 and thin-film resistance layer 150 includes resistance-metal contact portion 180 and resistance-resin contact portion 190. Resistance-resin contact portion 190 is scattered in resistance-metal contact portion 180. Thus, a contact area (or connection area) between via-hole conductor 130 and thin-film resistance layer 150 can be increased.

Furthermore, when resistance-resin contact portion 190 is scattered in resistance-via hole conductor contact portion 240, it is possible to relieve stress generated by a difference in a thermal expansion coefficient of metal part 230 made of low-melting point metal 200 and high-melting point metal 210 constituting via-hole conductor 130, or a thermal expansion coefficient of thin-film resistance layer 150, or a thermal expansion coefficient of insulating layer 120 that is brought into close contact with thin-film resistance layer 150, or the like.

As shown by arrow 170, an electric current flows from one via-hole conductor 130 to the other via-hole conductor 130 through thin-film resistance layer 150.

In resistance-via hole conductor contact portion 240, since electrical conduction is obtained through a plurality of resistance-metal contact portions 180, electrical connection is stabilized.

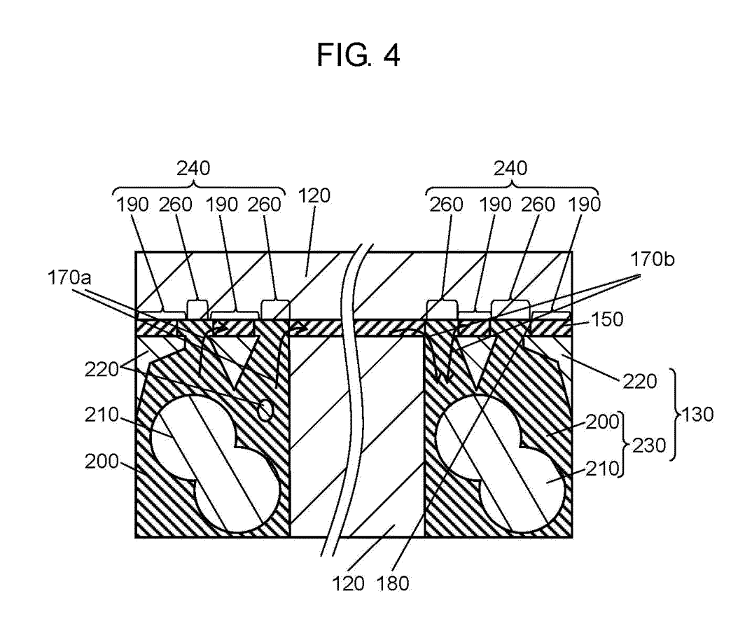

Next, a case where thin-film resistance layer 150 and a part of metal part 230 diffuse into each other in resistance-via hole conductor contact portion 240 is described with reference to FIG. 4.

FIG. 4 is another sectional schematic view for illustrating a connection portion between a thin-film resistance layer and a via-hole conductor of a resistance-formed substrate in accordance with the exemplary embodiment of the present invention. FIG. 4 corresponds to, for example, a part surrounded by dotted line 160 in FIG. 1. FIG. 4 is different from FIG. 2 in that diffusion portion 260 is formed in an interface portion.

In resistance-via hole conductor contact portion 240, a contact portion between thin-film resistance layer 150 and metal part 230 includes diffusion portion 260 (or a diffusion region, a diffusion layer).

In other words, diffusion portion 260 and resistance-resin contact portion 190 form resistance-via hole conductor contact portion 240. Metal part 230 of via-hole conductor 130 and thin-film resistance layer 150 are electrically and furthermore, physically coupled and integrated with each other via diffusion portion 260, thus enhancing the reliability of resistance-formed substrate.

Via-hole conductor 130 includes paste resin part 220, low-melting point metal 200, and high-melting point metal 210.

Low-melting point metal 200 includes low-melting point metal material having a melting point of 300° C. or lower (for example, a molten product of low-melting point metal powders of, for example, tin, bismuth, solder, or the like, having a melting point of 300° C. or lower, or an alloy of tin, bismuth, and solder with copper or silver). High-melting point metal 210 includes high-melting point metal material having a melting point of 900° C. or higher (high-melting point metal powder made of silver or copper, or an aggregated product thereof, or a part of silver powder or copper powder remaining without being alloyed with tin, bismuth, and solder).

Thin-film resistance layer 150 that is in contact with metal part 230 as diffusion portion 260 diffuses into low-melting point metal 200.

Thin-film resistance layer 150 that is in contact with paste resin part 220 remains as it is without diffusing. This is because paste resin part 220 inhibits diffusion of thin-film resistance layer 150 into low-melting point metal 200.

Note here that a side surface of thin-film resistance layer 150 (a side surface that is in contact with low-melting point metal 200) may be etched (furthermore, side-etched). The side surface of thin-film resistance layer 150 that is in contact with paste resin part 220 is side-etched and is narrowed, and thereby diffusion portion 260 is widened. However, since paste resin part 220 is brought into contact with thin-film resistance layer 150, not all of thin-film resistance layer 150 is lost.

Furthermore, when diffusion portion 260 is formed, physical strength of metal part 230 (or low-melting point metal 200) may be changed as compared with that before diffusion. In such a case, it is preferable that paste resin part 220 is allowed to remain such that it is in contact with diffusion portion 260 (furthermore, in a side-etched portion of thin-film resistance layer 150). In this way, when paste resin part 220 is allowed to remain in a side-etched portion, stress due to a difference in thermal expansion coefficients of various members in the side-etched portion can be reduced.

Herein, diffusion in diffusion portion 260 may be made in one direction or both directions of a metallic element or the like. Presence or absence of diffusion can be observed by analyzing a cross section of a sample to be evaluated by using an electron microscope or XMA (elemental analysis device). Furthermore, when the degree of diffusion proceeds, in one of metal part 230 and thin-film resistance layer 150 (for example, in a thinner one), the thickness may be reduced, or a dropping portion such as a pin-hole may be generated, or, furthermore, one of metal part 230 and thin-film resistance layer 150 may disappear (one of the metal parts disappears). In such cases, it is preferable that metal part 230 and thin-film resistance layer 150 are electrically and further physically coupled to each other through diffusion portion 260.

Since advantages of the resistance-formed substrate shown in FIG. 4 are common to those in FIG. 2, description thereof is omitted. It is preferable that via-hole conductor 130 and thin-film resistance layer 150 form diffusion portion 260 in which a part of elements (for example, Ni, and P) constituting thin-film resistance layer 150 is diffusing. Furthermore, it is preferable that diffusion portion 260 in which the part of elements (for example, Ni, and P) constituting thin-film resistance layer 150 is diffusing into low-melting point metal 200. In this way, by forming diffusion portion 260 in which a part of elements (for example, Ni, and P) constituting thin-film resistance layer 150 diffuses into via-hole conductor 130 side, the connection reliability between thin-film resistance layer 150 and via-hole conductor 130 can be enhanced.

In this way, it is preferable that thin-film resistance layer 150 and paste resin part 220 included in via-hole conductor 130 are electrically coupled to each other via diffusion portion 260 formed in the vicinity of the interface portion or the contact portion.

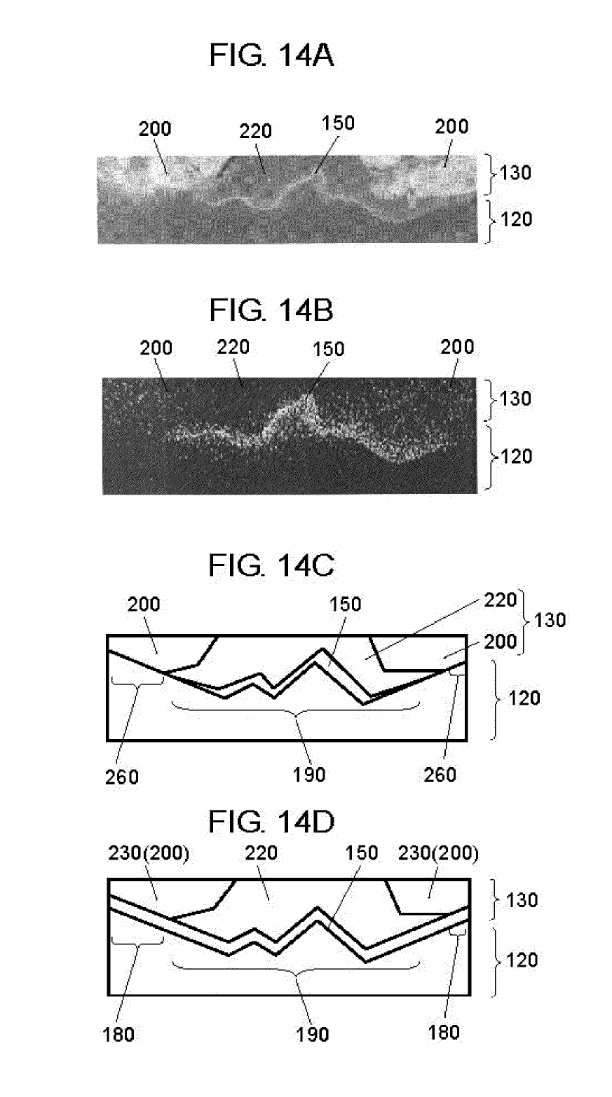

When thin-film resistance layer 150 is brought into surface contact with metal part 230 or low-melting point metal 200 included in via hole conductor 130 so as to form diffusion portion 260, it may be observed that a part of thin-film resistance layer 150 disappears in cross-sectional observation using, for example, an electron microscope as shown in FIG. 14A mentioned below. In FIG. 14A, it is observed that a part of thin-film resistance layer 150 disappears, and that an element constituting originally existing thin-film resistance layer 150 exists as diffusion portion 260 in via-hole conductor 130. Even when it is observed that a part of thin-film resistance layer 150 disappears, by forming diffusion portion 260 diffusing into via-hole conductor 130 side, the connection reliability between thin-film resistance layer 150 and via-hole conductor 130 can be enhanced.

Furthermore, diffusion portion 260 may be formed in a molten portion of Sn—Bi based solder powder, or an alloy part of Sn—Bi based solder and copper powder or silver powder (for example, a Sn—Cu alloy part, a Sn—Ag alloy part, or the like). This is because the melting points of these solder and alloy parts are 300° C. or lower, and a part of elements constituting thin-film resistance layer 150 can be easily dissolved or allowed to diffuse.

Both when it is observed that a part of thin-film resistance layer 150 disappears as shown in FIG. 4, and when it is observed that thin-film resistance layer 150 remains as shown in FIG. 2, excellent connection reliability can be obtained. This is because presence of disappearance of the part of thin-film resistance layer 150 is only one phenomenon accompanying formation of diffusion portion 260. Since the presence of disappearance is affected by a diffusion velocity or the like, it is affected by, for example, thicknesses, compositions, or heating conditions, of thin-film resistance layer 150. Whether or not diffusion portion 260 is formed can be determined by using an elemental analysis device (XMA or the like) attached to an electron microscope device.

It is preferable that not only low-melting point metal 200 and high-melting point metal 210 are provided, but also an ally part (the alloy part includes an intermetallic compound) in which a part of high-melting point metal 210 and low-melting point metal 200 are alloyed with each other is formed. It is preferable that a part of the alloy part forms a part of low-melting point metal 200, a part of elements constituting thin-film resistance layer 150 is dissolved or diffused, and diffusion portion 260 is formed.

FIG. 5 is another sectional schematic view for illustrating a connection portion between a via-hole conductor and a thin-film resistance layer in the resistance-formed substrate in accordance with the exemplary embodiment of the present invention. FIG. 5 corresponds to, for example, a part shown by dotted line 160 in FIG. 1.

FIG. 5 is different from FIG. 3 in that diffusion portion 260 is formed. The contact portion between via-hole conductor 130 and thin-film resistance layer 150 is originally in a state shown in FIG. 3. When a part of thin-film resistance layer 150 diffuses into via-hole conductor 130 and disappears, and diffusion portion 260 is formed, a state shown in FIG. 5 is obtained. Both in the state of FIG. 3 (state in which thin-film resistance layer 150 remains) and the state of FIG. 5 (state in which thin-film resistance layer 150 diffuses into via-hole conductor 130 and disappears), advantages of this exemplary embodiment can be obtained.

As shown in FIG. 5, resistance-via hole conductor contact portion 240 is a connection portion between via-hole conductor 130 and thin-film resistance layer 150, and includes diffusion portion 260 and resistance-resin contact portion 190. By scattering resistance-resin contact portion 190 in diffusion portion 260, a contact area between via-hole conductor 130 and thin-film resistance layer 150 is increased. Note here that FIG. 5 does not show the side-etched portion shown in FIG. 4.

As mentioned above, when diffusion portion 260 is formed, connection between via-hole conductor 130 and thin-film resistance layer 150 is further stabilized. As a result, a resistance value of the connection portion between thin-film resistance layer 150 and via-hole conductor 130 is hardly changed over time.

Note here that it is preferable that thin-film resistance layer 150 includes nickel as a main component. Furthermore, the content of nickel is desirably 60 wt. % or more and further desirably 80 wt. % or more. When the content of nickel is less than 60 wt. %, the structure shown in FIGS. 4 and 5 may not be obtained. Nickel has a high resistance value, and is not easily oxidized. Also, nickel has a low TCR (temperature change of resistance). Furthermore, by adding chromium (Cr) into nickel in thin-film resistance layer 150, the resistance value or the TCR can be further adjusted. Furthermore, when thin-film resistance layer 150 is formed by plating, it is preferable that phosphorus (P) is added to nickel (that is to say, a Ni—P plated film is formed). When phosphorus is added, formation of the plated film is stabilized. Phosphorus having a concentration of about 1% to 20%, and particularly preferably having a concentration of 10% is used. Furthermore, when thin-film resistance layer 150 formed of a plated film is used, the strength is enhanced, and properties and reliability are stabilized.

In this exemplary embodiment, via-hole conductor 130 and thin-film resistance layer 150 are brought into contact with each other at both paste resin part 220 and metal part 230. A configuration in which via-hole conductor 130 and thin-film resistance layer 150 are brought into contact with each other at both paste resin part 220 and metal part 230 is intended to include the configurations shown in FIGS. 4 and 5 are also included in addition to the configurations shown in FIGS. 2 and 3. As shown in FIGS. 4 and 5, even when diffusion portion 260 is formed in thin-film resistance layer 150, and opening is formed in a part of thin-film resistance layer 150, via-hole conductor 130 and thin-film resistance layer 150 are brought into contact with each other at both paste resin part 220 and metal part 230.

Furthermore, thin-film resistance layer 150 may be previously formed on a surface of copper foil 320 that forms wiring 140 by a method using vacuum, a formation method using plating, or the like.

Furthermore, resistance pattern 340 provided by patterning thin-film resistance layer 150, and wiring 140 pattern made of wiring 140 may be overlapped onto each other in part, or in patterns which are different from each other.

An example of a method for manufacturing a resistance-formed substrate described in FIGS. 1 to 5 are described with reference to drawings.

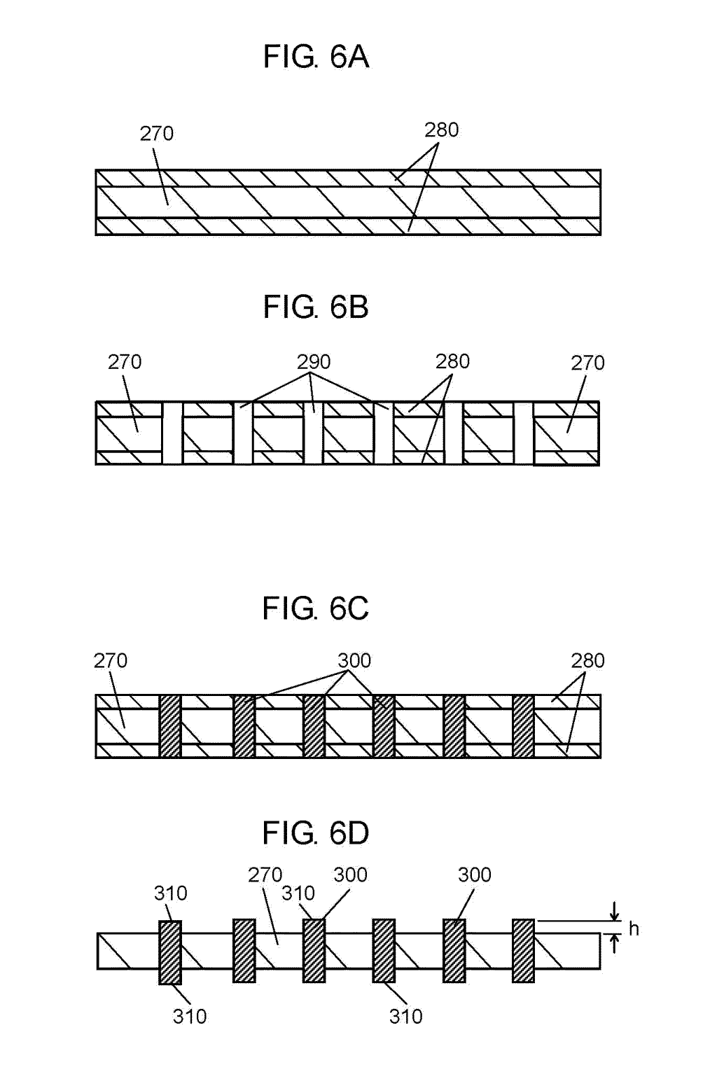

FIGS. 6A to 8C are sectional views showing a method for manufacturing a resistance-formed substrate in accordance with the exemplary embodiment of the present invention.

As shown in FIG. 6A, protective film 280 is bonded to at least one surface of prepreg 270. At this time, it is preferable that bonding is carried out by using adhesive strength (or tack strength) of prepreg 270.

Note here that a thickness of prepreg 270 is desirably 5 μm or more, further desirably 10 μm or more, and 15 μm or more. The thickness of prepreg 270 of less than 5 μm may make prepreg 270 expensive and affect the insulating property.

As protective film 280, it is preferable to use a PET film having a thickness of 5 μm or more and 300 μm or less. By adjusting the thickness of the PET film, protruding height (h) of protruding portion 310 of conductive paste 300 shown in FIG. 6D can be adjusted.

Next, as shown in FIG. 6B, through-holes 290 are formed in prepreg 270 to which protective film 280 is bonded. As a formation method of through-holes 290, a mechanical hole formation method by using a rotary drill that rotates at a high speed may be employed, but non-contact formation by, for example, irradiation with a laser beam is preferable. Furthermore, through-holes 290 are formed in such a manner that they penetrate through both protective film 280 and prepreg 270.

Next, as shown in FIG. 6C, through-holes 290 are filled with conductive paste 300. Preferable examples of a method for filling of conductive paste 300 include a method using a screen printing machine.

Thereafter, as shown in FIG. 6D, protective film 280 is peeled off for forming protruding portions 310 of conductive paste 300. Note here that protruding height (h) of conductive paste 300 from prepreg 270 can be adjusted by increasing and decreasing the thickness of protective film 280.

It is useful that a diameter of through-hole 290 is 30 μm or more 300 μm or less. The diameter of through-hole 290 of less than 30 μm may affect a filling property of conductive paste 300. Furthermore, when the diameter of through-hole 290 is more than 300 μm, meniscus is generated when conductive paste 300 is scraped, and the thickness of protruding portion 310 may vary. The meniscus herein denotes that, in a case of, for example, through-hole 290 having a diameter of more than 300 μm, conductive paste 300 is largely scraped in a middle part (or a center part) of a through-hole and the conductive paste remains without being scraped in the periphery (or a part that is in contact with protective film 280) of through-hole 290.

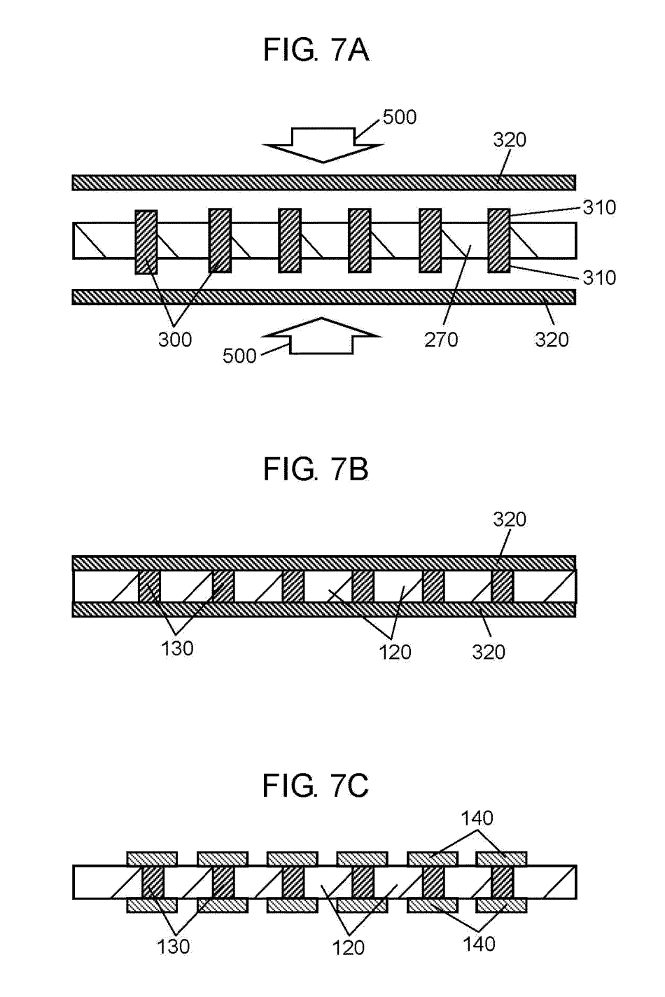

As shown in FIG. 7A, copper foil 320 is disposed to prepreg 270 provided with protruding portions 310 made of conductive paste 300, and pressurized, compressed, and laminated as shown by arrow 500. Note here that it is preferable that a press machine (a vacuum press machine, and furthermore, a vacuum heating and pressurizing press machine) is used when pressurization, compression, and lamination are carried out. Note here that FIG. 7A does not show a die or the like for pressurization and warming.

Then, further heating is carried out in a laminated state so as to connect conductive paste 300 and copper foil 320 to each other. Furthermore, prepreg 270 is thermally cured to obtain insulating layer 120. Thus, as shown in FIG. 7B, via-hole conductor 130 is formed. As shown in FIG. 2, via-hole conductor 130 includes paste resin part 220, low-melting point metal 200, and high-melting point metal 210.

After the state shown in FIG. 7B is obtained, copper foil 320 fixed to at least one surface of insulating layer 120 is patterned to form wiring 140, and thus a state shown in FIG. 7C is obtained.

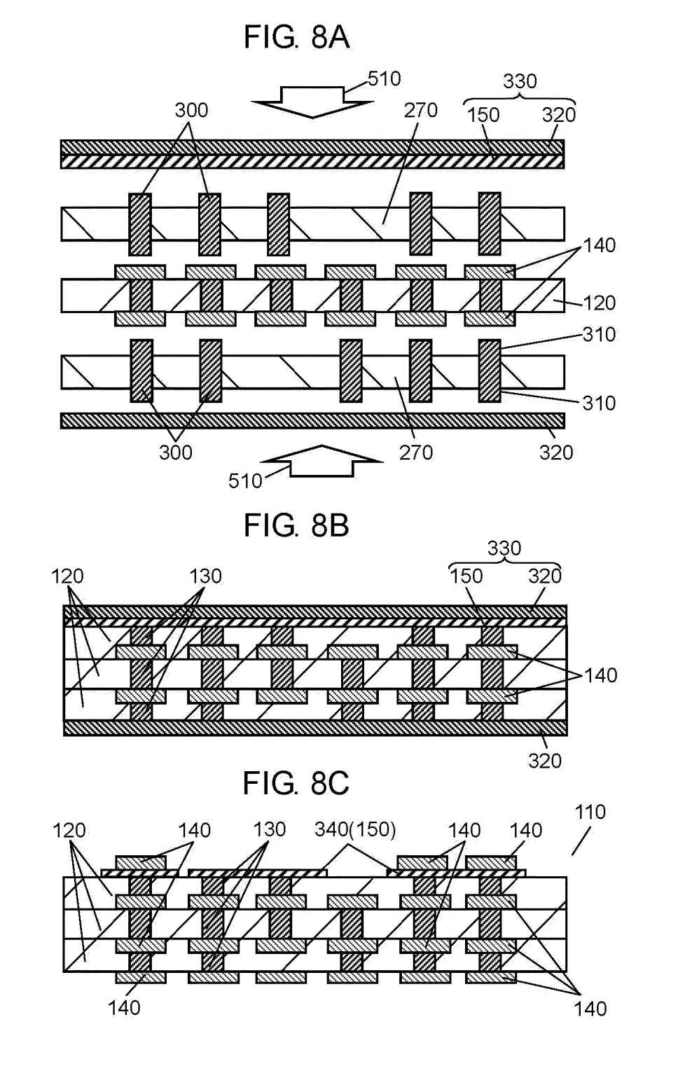

As shown in FIG. 8A, composite foil 330 is disposed on at least one surface of prepreg 270 provided with protruding portions 310 made of conductive paste 300 in such a manner that a thin-film resistance layer 150 side of composite foil 330 is a conductive paste 300 side, and is then pressurized, compressed, and laminated as shown by arrow 510.

As composite foil 330, it is preferable to use one provided previously with thin-film resistance layer 150 by plating, vacuum evaporation, sputtering, MOCVD, or the like, or plating (including wet plating and electroplating) on at least one surface or more of copper foil 320. A thickness of copper foil 320 is desirably 5 μm or more. The copper foil having a thickness of less than 5 μm may not be able to be easily handled due to shortage of strength even after thin-film resistance layer 150 is provided.

Furthermore, a thickness of thin-film resistance layer 150 is 0.01 μm or more and 10 μm or less (furthermore, 0.05 μm or more and 5 μm or less). When the thickness is less than 0.01 μm, in a case where thin-film resistance layer 150 is a simple substance, the strength of thin-film resistance layer 150 itself is deteriorated, a resistance value as resistance-formed substrate 110 may be changed. Note here that when thin-film resistance layer 150 is in a composite state, the thickness of thin-film resistance layer 150 can be made to be thinner than that in a case of a simple substance. This is because copper foil 320 as a backup is present on a rear surface of thin-film resistance layer 150. Herein, the case of a simple substance means that composite foil 330 does not include copper foil 320, and the case of the composite state means that composite foil 330 includes both copper foil 320 and thin-film resistance layer 150.

Note here that as shown in FIG. 8A, a wiring board produced in FIG. 7C is disposed to the other surface of prepreg 270 provided with protruding portions 310 made of conductive paste 300, and then pressurized, compressed, and laminated as shown by arrow 510. Note here that as a wiring board which is not provided with thin-film resistance layer 150, for example, a multilayer board having through-hole plating, a build-up substrate, or the like, may be used.

Conductive paste 300 is pressurized and brought into close contact with thin-film resistance layer 150 formed on one surface of composite foil 330 more strongly by a part of the height of protruding portion 310. Furthermore, by carrying out heating in a state in which a pressurize state is kept, conductive paste 300 is made into via-hole conductor 130. Furthermore, prepreg 270 is thermally cured to form insulating layer 120 by the heating, and thereby bond strength between thin-film resistance layer 150 and insulating layer 120 is enhanced. Thus, a state shown in FIG. 8B is obtained.

Thereafter, copper foil 320 and thin-film resistance layer 150 are patterned. In patterning, it is preferable to use a photosensitive resist or an etchant. Furthermore, composite foil 330 itself is patterned firstly (that is to say, copper foil 320 is etched, and then thin-film resistance layer 150 as a base of copper foil 320 is also patterned into the same shape). Thereafter, a part of copper foil 320 as an unnecessary part in patterned composite foil 330 is further removed by etching, and thereby a state shown in FIG. 8C is obtained. In FIG. 8C, copper foil 320 and thin-film resistance layer 150 are formed in different pattern shapes.

Thus, resistance-formed substrate 110 shown in FIG. 8C is formed. On the surface of resistance-formed substrate 110, wiring 140 obtained by patterning copper foil 320, or resistance pattern 340 obtained by patterning thin-film resistance layer 150 are formed. On resistance-formed substrate 110 shown in FIG. 8C, prepreg 270, conductive paste 300, or the like, may be further laminated. Thus, resistance-formed substrate 110 shown in FIG. 8C is subjected to steps described with reference to FIGS. 6A to 8A, and thereby a further multilayered substrate can be achieved.

Instead of copper foil 320 in FIG. 7A or copper foil 320 in FIG. 8A, composite foil 330 may be used. When a plurality of sheets of composite foil 330 are used in production of one resistance-formed substrate 110, a plurality of thin-film resistance layers 150 can be formed. Furthermore, thin-film resistance layers 150 may be provided on both surfaces (that is to say, upper and lower surfaces) of one via-hole conductor 130.

Also in FIG. 8A, a press machine (a vacuum press machine, and, furthermore, a vacuum heating and pressurizing press machine) may be used in pressurization, compression, and lamination. FIG. 8A does not show a die or the like for pressurization and warming.

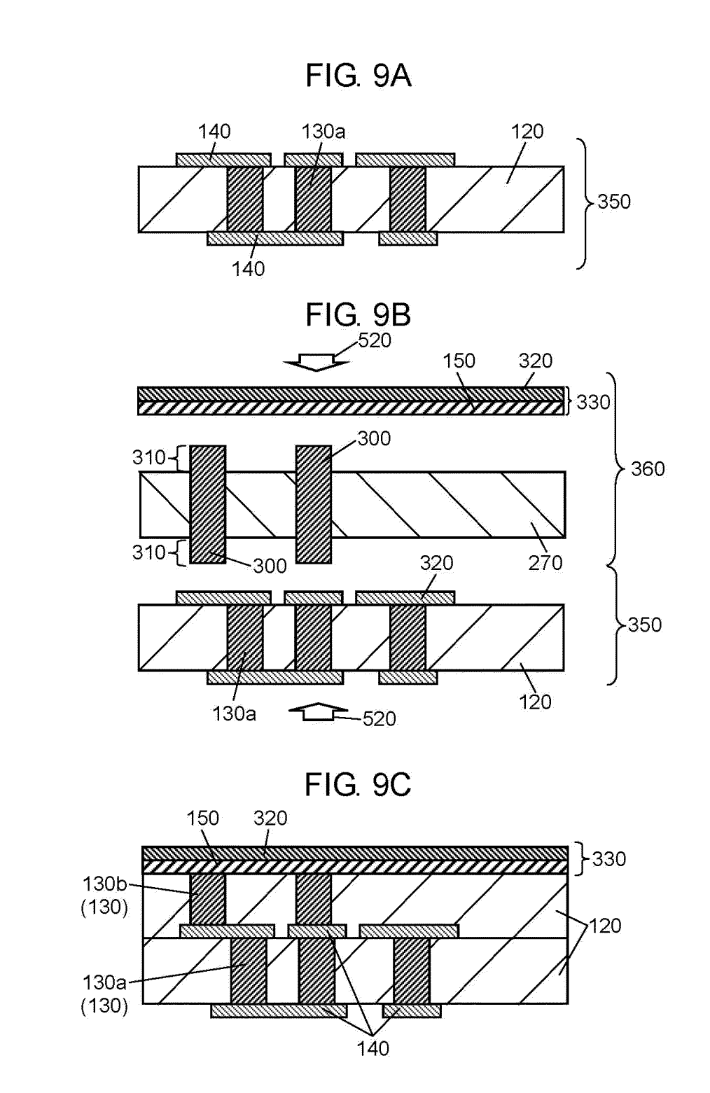

Next, with reference to FIGS. 9A to 11B, resistance-formed substrate 110 in another embodiment is described.

FIGS. 9A to 11B are sectional views showing a method for manufacturing a resistance-formed substrate including a buildup portion in accordance with the exemplary embodiment of the present invention.

As shown in FIG. 9A, core part 350 includes at least two layers more of wiring 140, via-hole conductor 130, and insulating layer 120. As via-hole conductor 130a constituting core part 350, plated via may be used, and a via may be made of conductive paste. The via made of conductive paste is not easily broken due to lamination pressure at the time of lamination shown in FIG. 9B.

FIG. 9B is a sectional view showing a state in which a buildup portion is laminated onto core part 350. In FIG. 9B, buildup portion 360 includes prepreg 270, conductive paste 300 which is filled in through-holes formed in prepreg 270 such that protruding portions 310 are provided, and composite foil 330. Furthermore, a conductive paste 300 side of the composite foil is defined as thin-film resistance layer 150 of composite foil 330.

Then, as shown in FIG. 9B, pressurization and heating are carried out shown by arrow 520. Then, as shown in the below-mentioned FIGS. 12A and 12B, low-melting point metal powder 390, high-melting point metal powder 400, and thin-film resistance layer 150, which are included in conductive paste 300, are brought into surface contact with each other. As low-melting point metal powder 390, solder powder including tin and bismuth is used. As high-melting point metal powder 400, silver powder, copper powder, or alloy powder including thereof are used.

In a heating step subsequent to the pressurizing step, conductive paste 300 is heated at a temperature of not lower than a melting point of low-melting point metal powder 390. With this heating, a surface of thin-film resistance layer 150 can be brought into contact with low-melting point metal powder 390, and thus, states shown in FIGS. 2 to 5 are obtained. Thus, a state shown in FIG. 9C is obtained. In FIG. 9C, conductive paste 300 is heated and melted to obtain via-hole conductor 130b.

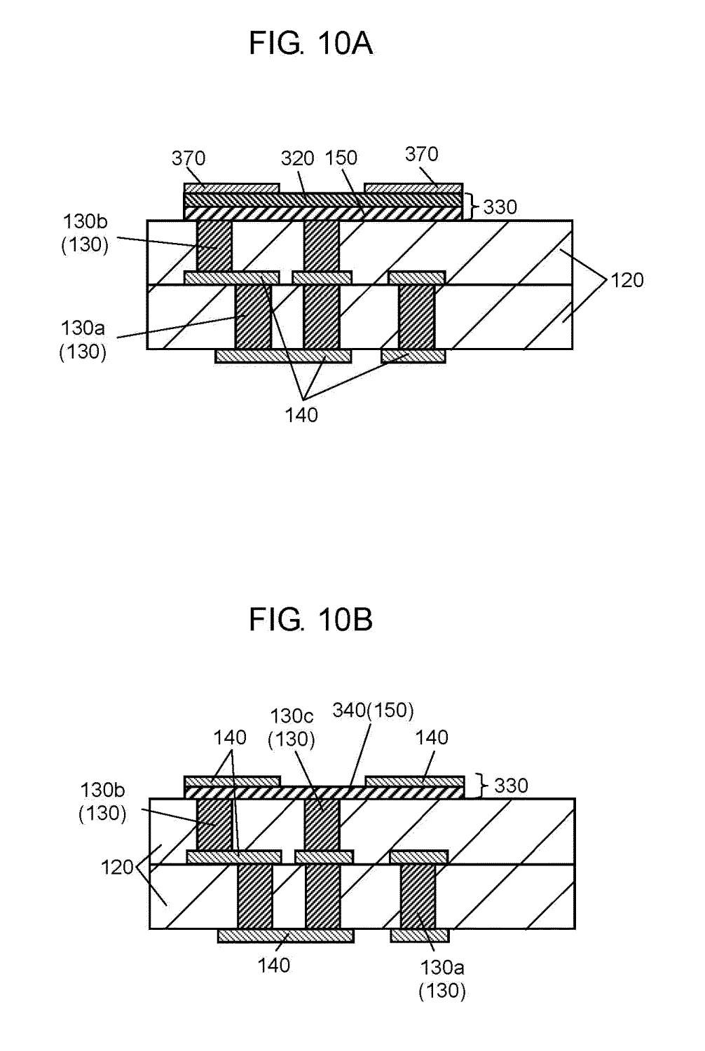

Composite foil 330 is etched into a predetermined pattern. Thereafter, as shown in FIG. 10A, resist 370 is formed into a predetermined pattern on a surface of composite foil 330. Thereafter, copper foil 320 is partially removed from composite foil 330 with the use of resist 370 as a mask. Then, resist 370 is removed. In this way, a shape shown in FIG. 10B is obtained.

In FIG. 10B, via-hole conductor 130b is brought into contact with resistance pattern 340 (thin-film resistance layer 150) of composite foil 330. Via-hole conductor 130c is brought into contact with resistance pattern 340 (thin-film resistance layer 150) in which copper foil 320 is removed from composite foil 330.

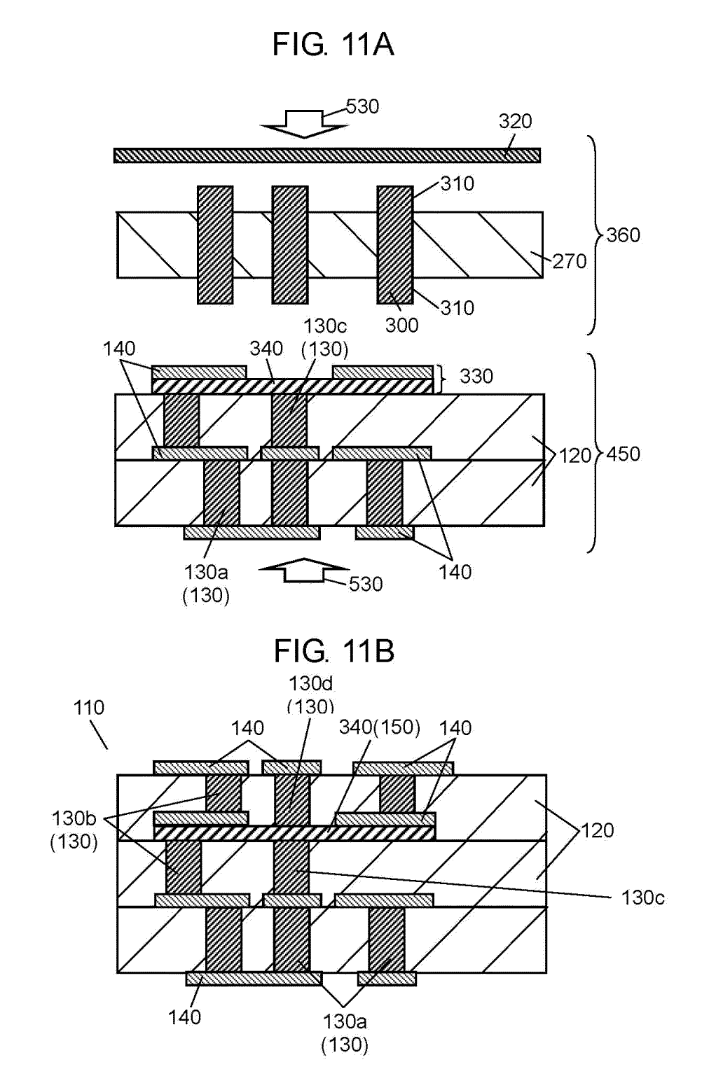

Next, as shown in FIG. 11A, buildup portion 360 is laminated on core part 450. Then, by carrying out pressurization as shown by arrow 530 and heating thereof, low-melting point metal powder 390 included in conductive paste 300 and high-melting point metal powder 400 having a melting point of 900° C. or higher are brought into surface contact with thin-film resistance layer 150 of composite foil 330 as shown in FIG. 12A mentioned below. Preferable examples of low-melting point metal powder 390 include solder powder including tin and bismuth. Preferable examples of high-melting point metal powder 400 include silver powder, copper powder, or alloy powder including thereof. In the pressurization and heating steps, conductive paste 300 is heated at a temperature of not lower than the melting point of low-melting point metal powder 390. Thus, a surface of thin-film resistance layer 150 and low-melting point metal powder 390 are brought into contact with each other reliably so as to obtain a state shown in FIGS. 2 to 5.

As mentioned above, a laminated body (or resistance-formed substrate 110) as shown in FIG. 11B is produced. At this time, heating is carried out at a temperature that is higher than a melting point temperature of low-melting point metal powder 390 (for example, Sn—Bi solder) included in conductive paste 300. For example, via-hole conductor 130 and thin-film resistance layer 150 can be directly connected to each other when they are heated to 200° C. and pressed while pressure is applied. Furthermore, when a part of thin-film resistance layer 150 is allowed to diffuse into low-melting point metal 200 constituting via-hole conductor 130, or low-melting point metal 200 and thin-film resistance layer 150 can be allowed to diffuse into each other, stable via connection can be achieved.

In this way, in this exemplary embodiment, thin-film resistance layer 150 (or resistance pattern 340) and a via-hole conductor made of conductive paste 300 can be electrically linked to each other directly.

Since thin-film resistance layer 150 such as NiP (nickel phosphorus) including nickel as a main component and containing phosphorus has an extremely thin a thickness such as a thickness of about 0.4 μm, thin-film resistance layer 150 is easily damaged. Therefore, in a state in which thin-film resistance layer 150 is exposed to a surface layer, disconnection easily occurs. Thus, as shown in FIG. 11A, it is desirable that prepreg 270 filled with predetermined conductive paste 300 is made into multilayer, and thin-film resistance layer 150 is incorporated into a substrate.

Note here that as shown in FIG. 11B, via-hole conductors 130c 130d may be formed on the upper and lower sides of thin-film resistance layer 150. When the upper and lower sides of thin-film resistance layer 150 are sandwiched by via-hole conductors 130c and 130d having low-melting point metal 200 (see FIG. 2), the electrical connection reliability and physical strength are enhanced.

Thus, conventionally, resistance is conducted through a Cu pad. However, according to a configuration shown in FIG. 11B, since electric conduction can be carried out through thin-film resistance layer 150 that is not provided with a Cu pad, the degree of freedom for designing a substrate is enhanced.

In FIG. 11A, as prepreg 270, composite material (material obtained by impregnating, for example, silica filler with epoxy resin), film base material (polyimide film or the like) may be used.

Thereafter, copper foil 320 is patterned so to obtain resistance-formed substrate 110 shown in FIG. 11B.

Next, a state in which connection stability between via-hole conductor 130 and thin-film resistance layer 150 is enhanced by providing protruding portion 310 is described with reference to FIGS. 12A to 12B.

FIGS. 12A to 12B are sectional schematic views for illustrating an effect of a protruding portion in accordance with the exemplary embodiment of the present invention.

FIG. 12A shows a sectional structure of conductive paste 300 before it is pressure-laminated. FIG. 12B shows a sectional structure of conductive paste 300 after it is pressure-laminated.

As shown in FIG. 12A, conductive paste 300 filled in through-holes formed in prepreg 270 such that it has protruding portion 310 is pressurized and compressed via composite foil 330 shown by arrow 540. Note here that conductive paste 300 includes low-melting point metal powder 390 (for example, solder powder including tin and bismuth), high-melting point metal powder 400 (for example, silver powder, copper powder, or alloy powder thereof), and uncured resin 380 (for example, uncured epoxy resin).

Next, as shown in FIG. 12B, protruding portion 310 made of conductive paste 300 is pressed to be crushed. Thus, high-melting point metal powder 400 and low-melting point metal powder 390 included in conductive paste 300 are deformed and brought into close contact with each other, so that density is increased.

In this compression step, a plurality of high-melting point metal powders 400 may be pressurized, deformed, and brought into surface contact with each other. Furthermore, a plurality of low-melting point metal powders 390 may be pressurized, deformed, and brought into surface contact with each other. Furthermore, high-melting point metal powder 400 and low-melting point metal powder 390 may be pressurized, deformed, and brought into surface contact with each other.

Furthermore, in this compression step, as shown in FIG. 12B, it is preferable that low-melting point metal powder 390 that is in contact with thin-film resistance layer 150 is further deformed. That is to say, preferred is a state in which a part of low-melting point metal powder 390 is pressurized, deformed, and brought into surface contact with thin-film resistance layer 150. With the surface contact, uncured resin 380 existing between thin-film resistance layer 150 and low-melting point metal powder 390 can be extruded to the outside of a surface contact portion.

As shown in FIG. 12B, conductive paste 300 is heated at not lower than the melting point of low-melting point metal powder 390 to be melted while a state in which low-melting point metal powder 390 that is adjacent to thin-film resistance layer 150 is deformed by pressurization, and is brought into surface contact with the surface of thin-film resistance layer 150. Thus, states shown in the above-mentioned FIGS. 2 to 5 are obtained.

Low-melting point metal 200 in via-hole conductor 130 is formed of low-melting point metal powder 390. Similarly, high-melting point metal 210 in via-hole conductor 130 is formed of high-melting point metal powder 400. Furthermore, paste resin part 220 is formed of uncured resin 380 included in conductive paste 300. Note here that paste resin part 220 and low-melting point metal 200 are securely brought into contact with the surface of thin-film resistance layer 150 as shown in FIGS. 2 to 3 through the steps shown in FIGS. 12A and 12B.

Low-melting point metal powder 390 made of, for example, solder including tin and bismuth is pressed onto thin-film resistance layer 150 to be deformed, and the deformed low-melting point metal powder 390 is physically brought into surface contact with thin-film resistance layer 150 via the surface contact portion. Thus, when low-melting point metal powder 390 is heated and melted, thin-film resistance layer 150 easily diffuse.

Furthermore, by diffusing a part of thin-film resistance layer 150 into low-melting point metal 200 with the heating, states shown in FIGS. 4 to 5 can be obtained.

Via-hole conductor 130 is formed by filling through holes 290 with conductive paste 300 including a low-melting point metal part (low-melting point metal 200) including tin and bismuth, or high-melting point metal filler such as copper or silver filler (high-melting point metal powder 400, or high-melting point metal 210), and a resin part (for example, paste resin part 220), followed by pressing and heating thereof.

Examples of thin-film resistance layer 150 include NiP (nickel phosphorus), NiB (nickel boron), or the like.

Note here that as composite foil 330, it is preferable that thin-film resistance layer 150 made of NiP or NiB thin film is formed by electroless plating on 18 μm equivalent copper foil 320 whose surface is appropriately roughened. A thickness of thin-film resistance layer 150 made of a NiP thin film is particularly preferably 0.04 μm or more and 0.5 μm or less although depending upon necessary resistance values. When the thickness is made to be 0.04 μm or more and 0.5 μm or less, a resistance value (surface resistivity) that is in a wide range from 25 Ω/sq to 250 Ω/sq is obtained. For measuring a film thickness, an evaluation method such as fluorescent X measurement is used.

However, in the contact surface (in particular, an interface portion) between thin-film resistance layer 150 and via-hole conductor 130, diffusion thickness is not higher than the detection limit (for example, less than 0.1 μm, or less than 1 μm) by usual detection means. That is to say, even when about 1% to 10% of the layer thickness of thin-film resistance layer 150 diffuses into via-hole conductor 130 in the contact portion, it may be observed that thin-film resistance layer 150 of the contact portion remains (does not disappear).

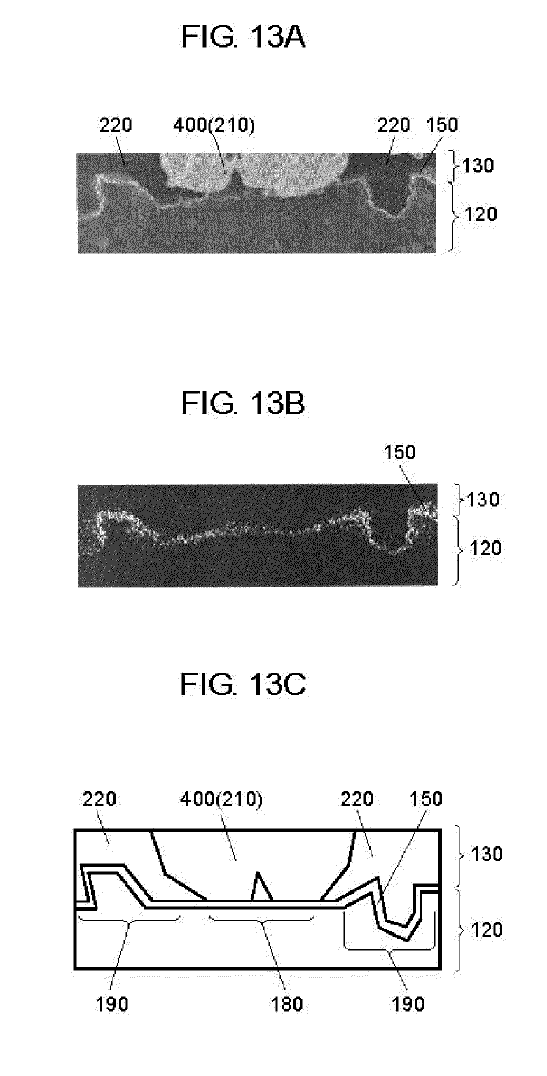

Next, microstructures of via-hole conductor 130 and insulating layer 120 of resistance-formed substrate 110 are described. FIG. 13A is an electron micrograph showing a contact portion between high-melting point metal 210 (high-melting point metal powder 400) of via-hole conductor 130 and thin-film resistance layer 150. FIG. 13B is a mapping photograph of electron micrograph at a Ni element in the contact portion between high-melting point metal 210 and thin-film resistance layer 150 shown in FIG. 13A. FIG. 13C is a schematic view of the electron micrograph of the contact portion between high-melting point metal 210 and thin-film resistance layer 150 shown in FIG. 13A.

High-melting point metal 210 is brought into contact (furthermore, surface contact) with thin-film resistance layer 150. Paste resin part 220 in via-hole conductor 130 is brought into close contact with a surface of thin-film resistance layer 150. Also for formation of the close contact state, as shown in FIGS. 12A and 12B mentioned above, it is preferable to use protruding portion 310 of conductive paste 300. As shown in FIG. 13B, thin-film resistance layer 150 includes Ni (nickel).

Next, with reference to FIGS. 14A to 14D, a contact portion between low-melting point metal 200 included in via-hole conductor 130 and thin-film resistance layer 150 is described.

FIG. 14A is an electron micrograph showing a contact portion between low-melting point metal 200 of via-hole conductor 130 and thin-film resistance layer 150. FIG. 14B is a mapping view of FIG. 14A. FIG. 14C is a schematic view of FIG. 14A. FIG. 14D is a schematic view of the contact portion between low-melting point metal 200 of via-hole conductor 130 and thin-film resistance layer 150. Low-melting point metal 200 is formed by melting low-melting point metal powder 390 shown in FIG. 12A.

Thin-film resistance layer 150 that has been in contact with low-melting point metal powder 390 diffuses and disappears. On the other hand, thin-film resistance layer 150 that is in contact (surface contact) with paste resin part 220 does not diffuse but remains in a mesh state or at random.

FIG. 14B is a mapping photograph at the Ni element in electron micrograph of the contact portion between low-melting point metal 200 and thin-film resistance layer 150 shown in FIG. 14A. Thin-film resistance layer 150 includes Ni (nickel). Furthermore, thin-film resistance layer 150 that has been contact with low-melting point metal 200 diffuses into low-melting point metal 200 and disappears.

FIG. 14C is a schematic view of the photograph shown in FIG. 14A. FIG. 14C shows a state in which a part of thin-film resistance layer 150 diffuses into low-melting point metal 200 and disappears. The state of FIG. 14C corresponds to, for example, states shown in FIG. 4 and FIG. 5.

Note here that it is not necessary to allow thin-film resistance layer 150 to diffuse into low-melting point metal 200 and to disappear as shown in FIGS. 14A to 14C. As shown in FIG. 14D, thin-film resistance layer 150 that is in contact with low-melting point metal 200 may remain as it is without diffusing. The state of FIG. 14D corresponds to, for example, states shown in FIG. 2 and FIG. 3.

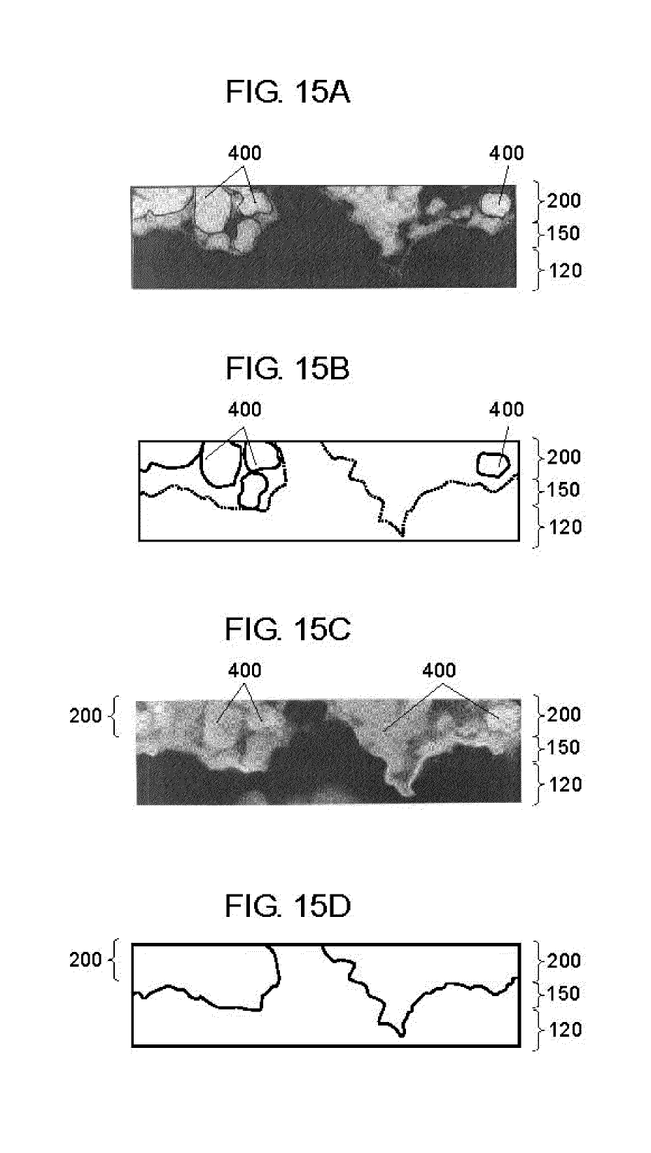

Next, with reference to FIGS. 15A to 15D, a case where thin-film resistance layer 150 remains in the contact portion between low-melting point metal 200 in via-hole conductor 130 and thin-film resistance layer 150 is described.

FIGS. 15A and 15C are electron micrographs of the contact portion between low-melting point metal 200 of via-hole conductor 130 and thin-film resistance layer 150. FIG. 15B is a schematic view of FIG. 15A. FIG. 15D is a schematic view of FIG. 15C. Thin-film resistance layer 150 may remain in the contact portion (surface interface) between low-melting point metal 200 and thin-film resistance layer 150. Also in this case, a part of the component elements (for example, Ni, P, or the like) of thin-film resistance layer 150 diffuse into low-melting point metal 200, and thereby connection reliability between low-melting point metal 200 and thin-film resistance layer 150 is enhanced.

Furthermore, in an interface at which thin-film resistance layer 150 and paste resin part 220 are brought into contact with each other, a Sn component as low-melting point metal 200 may be diffusing. In this case, it is preferable that thin-film resistance layer 150 and a diffusion layer of the Sn components of low-melting point metal 200 are brought into contact with each other and electrically connected to each other not at a point but at a surface.

As mentioned above, in diffusion portion 260, any one of low-melting point metal 200 and thin-film resistance layer 150 may remain or may disappear.

In formation of diffusion portion 260, heating is carried out at a temperature that is not lower than the melting point of low-melting point metal powder 390 in a state in which conductive paste 300 is pressure-laminated.

Furthermore, when a resistance-formed substrate is subjected to heating step (annealing step) at 200° C. or higher after the resistance-formed substrate is formed, diffusion portion 260 can be formed more reliably. When heating is carried out at 200° C. or higher, at the interface between via-hole conductor 130 and thin-film resistance layer 150, a part or more of Ni (or a Ni component) of thin-film resistance layer 150 can be allowed to diffuse and furthermore absorbed into a metal part (for example, low-melting point metal 200) of via-hole conductor 130. As a result, integration of the connection portion and high reliability can be achieved. Furthermore, the solder reflow is carried out along with heating at 200° C. or higher, it functions as a heating step (annealing step).

As shown in FIGS. 13A to 13C, in the contact portion (or the interface portion) between thin-film resistance layer 150 (for example, a NiP film) and via-hole conductor 130, it is preferable that Ni included in the thin-film resistance layer diffuses into low-melting point metal 200 to form a diffusion portion. Thus, via-hole conductor 130, and paste resin part 220 in via-hole conductor 130 may not form an interdiffusion portion. With such a structure (for example, the structure described in FIGS. 4 and 5 mentioned above), thin-film resistance layer 150 that is in contact with paste resin part 220 selectively remains (or remains in a scattered manner), so that stable via connection can be achieved.

Furthermore, when thin-film resistance layer 150 is allowed to diffuse and disappear, reflection noise or the like is not generated, so that an electrical property can be improved.

Note here that as shown in FIGS. 13A to 13C, in a place that is in contact with high-melting point metal powder 400 (or high-melting point metal 210), a thin film resister film including Ni as a main component (for example, thin-film resistance layer 150) clearly remains at the interface.

However, as shown in FIGS. 14A to 14C, thin film resister film 150 including Ni as a main component remains at the interface with respect to paste resin part 220 but thin-film resistance layer 150 disappears at the interface with respect to low-melting point metal 200 because the Ni component is absorbed and allowed to diffuse into low-melting point metal 200.

With the interface structure shown in FIGS. 14A to 14C, the reliability of the connection portion can be enhanced. Since, a diffusing (or disappearing) portion of thin-film resistance layer 150 and a remaining portion of the thin-film resistance layer (that is to say, a portion covered with paste resin part 220) are alternately disposed in a mesh state (or at random) and thin-film resistance layer 150 that is an alloy layer is dissolved in the surrounding thereof, the reliability is enhanced. Then, NiP and alloy paste are integrated with each other spuriously, and a P component diffuses into resin part 220, so that the connection thereof is strengthened.

As mentioned above, it is preferable that thin-film resistance layer 150 including Ni as a main component and via-hole conductor 130 form a diffusion portion and are electrically connected to each other directly.

Next, evaluation results of the reliability of resistance-formed substrate 110 are described with reference to Tables 1 to 4. Note here that evaluation by the moisture absorption reflow test, that is, MSL2 (Moisture Sensitivity Level 2) and MSL3 are carried out according to the standard of JEDEC (Joint Electron Device Engineering Council). JEDEC is one of EIA (Electronic Industries Alliance) organizations.

Tables 1 and 2 show one example of results of evaluation of reliability. Resistance-formed substrate S1 is formed as a comparative example by using thin-film resistance layer 150 and conventional copper paste. The conventional copper paste is conductive paste which is made of copper powder as high-melting point metal powder and thermo-setting resin and which is free from low-melting point metal powder 390. Furthermore, resistance-formed substrate E1 uses thin-film resistance layer 150 and conductive paste 300 of the present exemplary embodiment. The conductive paste 300 of the present exemplary embodiment is conductive paste including high-melting point metal powder 400, low-melting point metal powder 390, and uncured resin 380. Herein, as low-melting point metal powder 390, Bi—Sn based lead-free solder powder is used. Resistance-formed substrates S1 and E1, which are used for measurement of resistance value, are produced by the manufacturing method shown in FIGS. 6A to 8C.

In Tables 1 and 2, change of the values of 100-chain resistance (resistance provided by linking 100 via-hole conductors 130 connected to thin-film resistance layer 150) formed on resistance-formed substrates S1 and E1 is measured. Table 1 shows the change rate of the resistance value after the moisture absorption reflow test (MSL3) is carried out.

TABLE 1

| | Resistor-formed | Resistance-formed |
|---|---|---|
| | Substrate S1 | substrate E1 |
| Resistance change | 100% or more | 10% or less |
| rate | | |
| Evaluation result | No Good | Good |

In resistance-formed substrate S1 produced by using conventional conductive paste, the change rate of the via chain resistance is more than 100% in the moisture absorption reflow test (MSL3), and evaluation results are not good (No Good). In this way, in conventional resistance-formed substrate S1, stable connection may not be able to be achieved.

Next, a cause that makes the reliability insufficient in resistance-formed substrate S1 is considered. In resistance-formed substrate S1, it seems that adhesiveness between the via-hole conductor and thin-film resistance layer 150 is insufficient although high pressure welding is carried out between the conventional via paste and thin-film resistance layer 150. This is because connection between thin-film resistance layer 150 and via-hole conductor 130 is mainly based on pressure contact in resistance-formed substrate S1 using conventional via paste.

On the contrary, in resistance-formed substrate E1, even when 260° C. moisture absorption reflow at the level 3 of JEDEC is carried out, the change rate of the via chain resistance value is 10% or less, and good evaluation result is obtained (referred to as “Good”).

In resistance-formed substrate E1, connection between thin-film resistance layer 150 and via-hole conductor 130 has a configuration shown in FIGS. 2 to 5 mentioned above, excellent reliability is achieved.

Table 2 shows the change rate of the resistance value after a thermal-shock test is carried out at temperatures from −40° C. to 125° C.

TABLE 2

| | Resistor-formed | Resistance-formed |
|---|---|---|
| | Substrate S1 | substrate E1 |
| Resistance change | 100% or more | 20% or less |
| rate | | |
| Evaluation result | No Good | Good |

In resistance-formed substrate S1 produced by using a conventional conductive paste, in a vapor phase thermal-shock test at temperatures from −40° C. to 125° C., the change rate of the via chain resistance is more than 100%, and evaluation result of the thermal-shock test is not good (referred to as “No Good”).

Next, a cause that makes the reliability insufficient in resistance-formed substrate S1 is considered. In conventional resistance-formed substrate S1, it seems that to be because adhesiveness between via-hole conductor and thin-film resistance layer 150 is insufficient although conventional via paste and thin-film resistance layer 150 are connected by high pressure welding. This is because connection between thin-film resistance layer 150 and via-hole conductor 130 is mainly based on pressure contact in the resistance-formed substrate experimentally produced using conventional via paste.

On the contrary, in resistance-formed substrate E1 using conductive paste 300, in a vapor phase thermal-shock test at temperatures from −40° C. to 125° C., the change rate of the via chain resistance value is 20% or less, and the evaluation result is good (referred to as “Good”).

In resistance-formed substrate E1, thin-film resistance layer 150 and via-hole conductor 130 are connected to each other as in a configuration shown in FIGS. 2 to 5, excellent reliability is obtained.

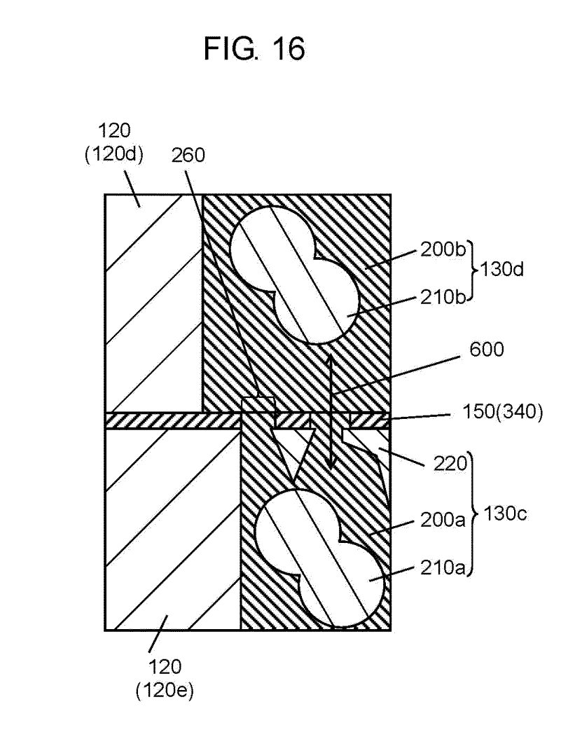

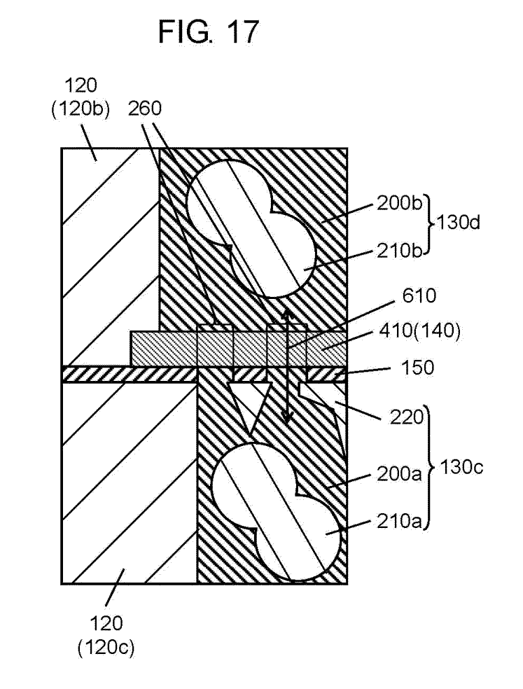

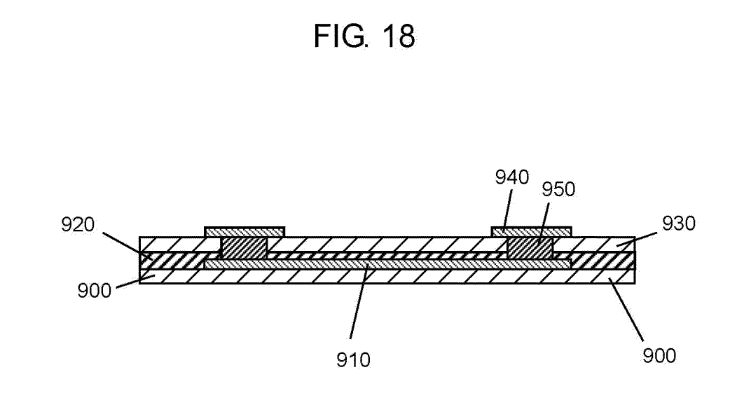

Next, with reference to FIGS. 16 and 17, a structure of a connection portion between thin-film resistance layer 150 (or resistance pattern 340) and via-hole conductors 130c and 130d is described. On the upper and lower parts of thin-film resistance layer 150, via-hole conductors 130c and 130d are formed.

FIG. 16 is a sectional schematic view showing a via-hole conductor in accordance with the exemplary embodiment of the present invention. FIG. 17 is a sectional schematic view showing a via-hole conductor in a case where a copper pad is formed in accordance with the exemplary embodiment of the present invention. In FIGS. 16 and 17, via-hole conductors 130c and 130d and thin-film resistance layer 150 are strongly integrated with each other.

FIG. 16 shows a via connection portion in which via-hole conductors 130c and 130d are provided to the lower and upper parts of thin-film resistance layer 150.

Via-hole conductor 130c is formed in insulating layer 120e that is provided to the lower side of thin-film resistance layer 150. Via-hole conductor 130d is formed in insulating layer 120d that is provided to the upper side of thin-film resistance layer 150. Via-hole conductors 130c and 130d are formed in such a manner that parts of them are overlapped with each other.

As shown in FIG. 16, it is preferable that diffusion portions 260 are formed at random (or in a network state, or a dotted state) in the surface, which is in contact with via-hole conductors 130c and 130d, of thin-film resistance layer 150. As shown by arrow 600, via-hole conductor 130c and via-hole conductor 130d are physically integrated with each other through diffusion portion 260, so that mechanical strength is enhanced and electrical connection becomes stable.

FIG. 17 shows a via connection portion in a case where copper pad 410 is formed on thin-film resistance layer 150. Via-hole conductor 130c is formed in insulating layer 120e that is provided to the lower side of thin-film resistance layer 150. Via-hole conductor 130d is formed in insulating layer 120d that is provided to the upper side of thin-film resistance layer 150. Via-hole conductors 130c and 130d are formed in such a manner that parts of them are overlapped with each other.

Then, copper pad 410 (or wiring 140) is provided to the upper side of thin-film resistance layer 150 (or resistance pattern 340), and via-hole conductor 130d is formed on copper pad 410 (or wiring 140).

With a configuration of FIG. 17, as shown by arrow 610, electrical connection between via-hole conductor 130c and via-hole conductor 130d becomes more stable. Furthermore, these members are integrated with each other also physically. In particular, when tin-bismuth based solder is used as low-melting point metal 200 for via-hole conductor 130c, solder including tin and bismuth included in via-hole conductor 130c is directly coupled to copper pad 410 (or wiring 140) through diffusion portions 260 having a network structure (or a mesh structure). As a result, a copper-tin alloy (a copper-tin metallic compound) is formed in the connection portion, so that via-hole conductor 130c and copper pad 410 are integrated with each other and the connection reliability is improved.

Next, Tables 3 and 4 show one example of the results of examination of the effect of copper pad 410 in resistance-formed substrate 110 in accordance with the present exemplary embodiment.

Resistance-formed substrates E2 and E3 are formed by using thin-film resistance layer 150, and conductive paste 300 (including high-melting point metal powder 400, low-melting point metal powder 390, and uncured resin 380) of this exemplary embodiment. Resistance-formed substrates E2 and E3 that are used for measurement of a resistance value are produced by the method shown in FIGS. 6A to 8C. Furthermore, in resistance-formed substrate E2, copper pad 410 is formed on one surface of insulating layer 120, and thin-film resistance layer 150 is formed on the other surface (one-sided Cu pad). In resistance-formed substrate E3, copper pad 410 is formed on one surface of insulating layer 120, and copper pad 410 is formed on the other surface via thin-film resistance layer 150 (double-sided Cu pad).

Tables 3 and 4 show change of the resistance value of thin-film resistance layer 150 provided by linking 100-chain resistance formed in resistance-formed substrates E2 and E3. Table 3 shows a change rate of the resistance value after the moisture absorption reflow test (MSL2) is carried out. Table 4 shows a change rate of the resistance value after a thermal-shock test at temperatures from −40° C. to 125° C. is carried out.

TABLE 3

| | Resistor-formed | Resistance-formed |
|---|---|---|
| | Substrate E2 | substrate E3 |
| | (one-sided Cu pad) | (double-sided Cu pad) |
| Resistance | 20% or less | 5% or less |
| change rate | | |
| Evaluation | Good | Better |
| result | | |

TABLE 4

| | Resistor-formed | Resistance-formed |
|---|---|---|
| | Substrate E2 | substrate E3 |
| | (one-sided Cu pad) | (double-sided Cu pad) |
| Resistance | 20% or more | 5% or less |
| change rate | | |
| Evaluation | Good | Better |
| result | | |

From Tables 3 and 4, it is shown that the change rate of resistance-formed substrate E3 is smaller than that of resistance-formed substrate E2. That is to say, when copper pad 410 is provided on both sides of insulating layer 120, connection reliability is further improved.

Note here that the shape of copper pad 410 may be formed in a land pattern in such a manner that it surrounds via patterns, or may be a part of patterns of wiring 140.

### INDUSTRIAL APPLICABILITY

According to the present exemplary embodiment, a resistance-formed substrate whose via connection portion has high reliability is obtained.

### REFERENCE MARKS IN THE DRAWINGS

110 resistance-formed substrate
120, 120a, 120b, 120c, 120d, 120e insulating layer
130, 130a, 130b, 130c, 130d via-hole conductor
140, 140a, 140b wiring
150 thin-film resistance layer
160 dotted line
170, 170a, 170b, 172, 500, 510, 520, 530, 540, 600, 610 arrow
180 resistance-metal contact portion
190 resistance-resin contact portion
200 low-melting point metal
210 high-melting point metal
220 paste resin part
230 metal part
240 resistance-via hole conductor contact portion
260 diffusion portion
270 prepreg
280 protective film
290 through-hole
300 conductive paste
310 protruding portion
320 copper foil
330 composite foil
340 resistance pattern
350, 450 core part
360 buildup portion
370 resist
380 uncured resin
390 low-melting point metal powder
400 high-melting point metal powder
410 copper pad

1. A resistance-formed substrate comprising:
a first insulating layer;
a first wiring formed on a first surface of the first insulating layer;
a thin-film resistance layer formed on a second surface of the first insulating layer and including nickel as a main component; and
a first via-hole conductor penetrating through the first insulating layer, and electrically connected to the first wiring and the thin-film resistance layer,
wherein the first via-hole conductor includes:
a metal part including
a low-melting point metal including tin and bismuth and having a melting point of 300° C. or lower, and
a high-melting point metal including at least one of copper and silver and having a melting point of 900° C. or higher; and
a paste resin part, and
wherein the first via-hole conductor is brought into contact with the thin-film resistance layer at both the paste resin part and the metal part.

2. The resistance-formed substrate of claim 1, further comprising:
a second wiring coupled to the first via-hole conductor via the thin-film resistance layer on the second surface of the insulating layer.

3. The resistance-formed substrate of claim 2,
wherein the thin-film resistance layer is integrated with the second wiring.

4. The resistance-formed substrate of claim 3,
wherein the thin-film resistance layer is brought into surface contact with a surface of the second wiring.

5. The resistance-formed substrate of claim 2,
wherein the thin-film resistance layer has a different shape from that of the second wiring.

6. The resistance-formed substrate of claim 1, further comprising:
a diffusion portion in which nickel included in the thin-film resistance layer diffuses into the metal part, and
wherein the metal part and the thin-film resistance layer are coupled to each other through the diffusion portion.

7. The resistance-formed substrate of claim 1,
wherein the thin-film resistance layer includes phosphorus.

8. The resistance-formed substrate of claim 1,
wherein the paste resin part is scattered in a contact portion between the thin-film resistance layer and the first via-hole conductor.

9. The resistance-formed substrate of claim 1, further comprising:
a second insulating layer laminated on the second surface of the first insulating layer.

10. The resistance-formed substrate of claim 9, further comprising:
a second via-hole conductor penetrating through the second insulating layer and connected to the thin-film resistance layer.

11. The resistance-formed substrate of claim 1, further comprising:
a third insulating layer laminated on the first surface of the first insulating layer.

12. A method for manufacturing a resistance-formed substrate, the method comprising:
bonding a protective film to at least one surface of prepreg;
forming through-holes by perforating the prepreg covered with the protective film from an outer side of the protective film;
filling the through-holes with conductive paste including
a low-melting point metal powder including tin and bismuth, and having a melting point of 300° C. or lower,
a high-melting point metal powder including at least one of copper and silver, and having a melting point of 900° C. or higher, and
uncured resin;
forming protruding portions by peeling off the protective film such that a part of the conductive paste protrudes from each of the through-holes;
disposing and pressure-laminating composite foil formed by laminating a thin-film resistance layer including nickel as a main component and copper foil onto each other on the protruding portion, such that the thin-film resistance layer is disposed to a conductive paste side; and
heating the conductive paste to a temperature not lower than a melting point of the low-melting point metal powder.

13. The method for manufacturing a resistance-formed substrate of claim 12,
wherein further heating at a temperature of 200° C. or higher is carried out after the heating of the conductive paste.
